(19) United States
(12) Patent Application Publication
(10) Pub. No.: US 2020/0335394 A1
(43) Pub. Date: Oct. 22, 2020

(54) METHOD OF MANUFACTURING SUBSTRATE AND THE SAME SUBSTRATE

(71) Applicant: EBARA CORPORATION, Tokyo (JP)

(72) Inventors: Keiichi KURASHINA, Tokyo (JP); Taiki ISHITSUKA, Tokyo (JP); Shinji OMATA, Tokyo (JP); Mitsuhiro SHAMOTO, Tokyo (JP); Makoto KUBOTA, Tokyo (JP)

(21) Appl. No.: 16/090,059

(22) PCT Filed: Mar. 29, 2017
(86) PCT No.: PCT/JP2017/012896

§ 371 Date: Sep. 28, 2018

(30) Foreign Application Priority Data
Mar. 31, 2016 (JP) 2016-071000

(51) Int. Cl. H01L 21/768; H01L 21/02; H01L 23/532; H01L 23/00

(52) U.S. Cl. CPC H01L 21/76873; H01L 21/02535; H01L 2224/11462; H01L 24/11; H01L 23/53238

(57) ABSTRACT

To prevent a tin alloy from coming into contact with a copper wiring layer when a tin alloy bump layer is reflowed. According to an aspect of the present invention, a method of manufacturing a substrate having a bump at a resist opening is provided. The method of manufacturing a substrate includes a step of forming a copper wiring layer on the substrate by plating at a first temperature, a step of forming a barrier layer on the copper wiring layer by plating at a second temperature that is approximately equal to the first temperature, and a step of forming a tin alloy bump layer on the barrier layer by plating.

### TECHNICAL FIELD

The present invention relates to a method of manufacturing a substrate and the same substrate.

### BACKGROUND ART

It is common practice to form a wire in a fine wiring groove, a hole or a resist opening formed in a surface of a substrate, such as a semiconductor wafer, or form a bump (protruding electrode) to be electrically connected to an electrode or the like of a package on a surface of a substrate. As a process of forming such a wire or bump, electrolytic plating, vapor deposition, printing, and ball bumping are known, for example. In recent years, with the increase in number of I/Os and the decrease in pitch of semiconductor chips, the electrolytic plating, which is ready for miniaturization and is relatively stable in performance, has become more commonly used.

When the electrolytic plating is used to form a wire or a bump, a seed layer (power supply layer) having low electric resistance is formed on a surface of a barrier metal that is formed in a wiring groove, a hole or a resist opening in the substrate (see PTL1, for example).

### CITATION LIST

### Patent Literature

PTL1: Japanese Patent Laid-Open No. 2014-60379

### SUMMARY OF INVENTION

### Technical Problem

Such a electrolytic plating is used for manufacturing a substrate that has a bump at a resist opening. FIGS. 6A to 6F are schematic diagrams for illustrating a conventional process of manufacturing a substrate that has a bump at a resist opening.

As shown in FIG. 6A, first, a substrate W made of SiO₂ or Si is prepared. A seed layer 201 of copper or the like is formed on the substrate W, and a resist layer 202 having a predetermined pattern is formed on the seed layer 201. As shown in FIG. 6B, a copper wiring layer 203 is then formed in an opening in the resist layer 202 by electrolytic plating. The temperature of the plating solution used when the copper wiring layer 203 is formed is set at approximately 25° C., from the viewpoints of the plating rate and the efficacy of the additive contained in the plating solution, for example.

As shown in FIG. 6C, a barrier layer 204 containing Ni is formed on the copper wiring layer 203 by electrolytic plating. The temperature of the plating solution used when the barrier layer 204 is formed is set at approximately 40° C., from the viewpoints of the plating rate and the efficacy of the additive contained in the plating solution, for example. In this way, the barrier layer 204 formed on top of the copper wiring layer 203 is generally formed by at a higher plating temperature than the copper wiring layer 203.

The temperature of the resist layer 202 is affected by the temperature of the plating solution used when the copper wiring layer 203 is formed and the temperature of the plating solution used when the barrier layer 204 is formed. That is, when the copper wiring layer 203 is formed, the temperature of the resist layer 202 is close to approximately 25° C., which is the temperature of the plating solution used when the copper wiring layer 203 is formed. When the barrier layer 204 is formed, the temperature of the resist layer 202 is close to approximately 40° C., which is the temperature of the plating solution used when the barrier layer 204 is formed. When the barrier layer 204 is formed, the resist layer 202 is at a higher temperature than when the copper wiring layer 203 is formed, and therefore thermally expands. As a result of the thermal expansion of the resist layer 202, as shown in FIG. 6C, the width of the opening in the resist layer 202 decreases when the barrier layer 204 is formed, and as a result, the width of the barrier layer 204 is smaller than the width of the copper wiring layer 203. In this specification, the “width” means the outer diameter of each layer when the opening in the resist layer 202 has a substantially circular shape and means the distance between apexes of each polygonal layer when the opening in the resist layer 202 has a polygonal shape.

As shown in FIG. 6D, a tin alloy bump layer 205 containing tin and silver then is formed on the barrier layer 204 by electrolytic plating. The temperature of the plating solution used when the tin alloy bump layer 205 is formed is set at approximately 30° C., from the viewpoints of the plating rate and the efficacy of the additive contained in the plating solution, for example. When the tin alloy bump layer 205 is formed, the resist layer 202 is at a lower temperature than when the barrier layer 204 is formed, and therefore thermally shrinks. As a result of the thermal shrinkage of the resist layer 202, as shown in FIG. 6D, the width of the opening in the resist layer 202 increases when the tin alloy bump layer 205 is formed, and as a result, the width of the tin alloy bump layer 205 is greater than the width of the barrier layer 204.

The resist layer 202 is then removed by a resist stripping device, and the seed layer 201 is etched into a more appropriate shape by an etching device. As shown in FIG. 6E, the copper wiring layer 203, the barrier layer 204 and the tin alloy bump layer 205 have different widths. Specifically, the barrier layer 204 has a smaller width than the copper wiring layer 203.

If the barrier layer 204 has a smaller width than the copper wiring layer 203, when the tin alloy bump layer 205 is reflowed, as shown in FIG. 6F, the reflowed tin alloy bump layer 205 may flow down along the side surface of the barrier layer 204 and come into contact with the copper wiring layer 203. If the tin alloy bump layer 205 comes into contact with the copper wiring layer 203, the copper may diffuse into the tin alloy to cause degradation of the bonding strength of the bump or cause an electromigration that causes a brake of wiring. Such problems do not arise only when a structure of three plating layers is formed by electrolytic plating but may arise when a three-layer structure is formed by electroless plating.

The present invention has been devised in view of the circumstances described above. An object of the present invention is to prevent a tin alloy from coming into contact with a copper wiring layer when a tin alloy bump layer is reflowed.

### Solution to Problem

According to an aspect of the present invention, a method of manufacturing a substrate having a bump at a resist opening is provided. The manufacturing method includes a step of forming a copper wiring layer on the substrate by plating with a plating solution at a first temperature, a step of forming a barrier layer on the copper wiring layer by plating with a plating solution at a second temperature that is approximately equal to the first temperature, and a step of forming a tin alloy bump layer on the barrier layer by plating.

According to this aspect, the barrier layer formed on the copper wiring layer is formed by plating at a temperature approximately equal to the temperature at the time when the copper wiring layer is formed by plating. Therefore, the width of the resist opening at the time when the barrier layer is formed by plating is close to the width of the resist opening at the time when the copper wiring layer is formed by plating. As a result, the width of the barrier layer is close to the width of the copper wiring layer, and when the tin alloy bump layer is reflowed, the tin alloy can be prevented from flowing down to and coming into contact with the copper wiring layer.

According to an aspect of the present invention, the difference between the first temperature and the second temperature is less than 5° C.

According to this aspect, since the difference between the first temperature and the second temperature is less than 5° C., the width of the barrier layer is close to the width of the copper wiring layer, and when the tin alloy bump layer is reflowed, the tin alloy can be prevented from flowing down to and coming into contact with the copper wiring layer.

According to an aspect of the present invention, the difference between the first temperature and the second temperature is 2.5° C. or less.

According to this aspect, since the difference between the first temperature and the second temperature is less than 2.5° C., the width of the barrier layer is even closer to the width of the copper wiring layer, and when the tin alloy bump layer is reflowed, the tin alloy can be prevented with higher reliability from flowing down to and coming into contact with the copper wiring layer.

According to an aspect of the present invention, the difference between the first temperature and the second temperature is 1° C. or less.

According to this aspect, since the difference between the first temperature and the second temperature is less than 1° C., the width of the barrier layer is substantially equal to the width of the copper wiring layer, and when the tin alloy bump layer is reflowed, the tin alloy can be prevented with even higher reliability from flowing down to and coming into contact with the copper wiring layer.

According to an aspect of the present invention, the barrier layer contains one or more metals selected from a group consisting of Ni and Co.

According to this aspect, since the barrier layer is made of a material into which copper of the copper wiring layer is hard to diffuse, the copper of the copper wiring layer can be prevented from diffusing into the tin alloy of the tin alloy bump layer. Typically, the layer of Ni or Co can be formed by electrolytic plating.

According to an aspect of the present invention, a method of manufacturing a substrate having a bump at a resist opening is provided. The method of manufacturing a substrate includes a step of forming a copper wiring layer on the substrate by plating with a plating solution at a first temperature, a step of forming an enhanced barrier layer on the copper wiring layer by plating with a plating solution at a second temperature that is lower than the first temperature, and a step of forming a tin alloy layer on the enhanced barrier layer by plating.

According to this aspect, the enhanced barrier layer on the copper wiring layer is formed by plating at a temperature lower than the temperature at the time when the copper wiring layer is formed by plating. Therefore, the width of the resist opening at the time when the enhanced barrier layer is formed by plating is greater than the width of the resist opening at the time when the copper wiring layer is formed by plating. Therefore, the width of the enhanced barrier layer is greater than the width of the copper wiring layer, and when the tin alloy bump layer is reflowed, the tin alloy can be prevented with higher reliability from flowing down to and coming into contact with the copper wiring layer.

According to an aspect of the present invention, the width of the enhanced barrier layer is greater than the width of the copper wiring layer.

According to this aspect, since the width of the enhanced barrier layer is greater than the width of the copper wiring layer, when the tin alloy bump layer is reflowed, the tin alloy can be prevented with even higher reliability from flowing down to and coming into contact with the copper wiring layer.

According to an aspect of the present invention, the enhanced barrier layer covers at least a part of a side surface of the copper wiring layer.

According to this aspect, since the enhanced barrier layer covers at least a part of a side surface of the copper wiring layer, when the tin alloy bump layer is reflowed, the tin alloy can be prevented with even higher reliability from flowing down to and coming into contact with the copper wiring layer.

According to an aspect of the present invention, the second temperature is lower than the first temperature by 5° C. or more and is equal to or higher than 15° C.

According to this aspect, since the second temperature is lower than the first temperature by 5° C. or more, the width of the enhanced barrier layer can be sufficiently greater than the width of the copper wiring layer. Therefore, the tin alloy can be prevented with higher reliability from coming into contact with the copper wiring layer. Some kinds of plating solution used for forming the enhanced barrier layer by plating contain boric acid. Boric acid can be deposited if the temperature of the plating solution is lower than 15° C. According to this aspect, since the second temperature is equal to or higher than 15° C., boric acid can be prevented from being deposited from the plating solution used for forming the enhanced barrier layer by plating.

According to an aspect of the present invention, the enhanced barrier layer contains one or more metals selected from a group consisting of Ni and Co.

According to this aspect, since the enhanced barrier layer is made of a material into which copper of the copper wiring layer is hard to diffuse, the copper of the copper wiring layer can be prevented from diffusing into the tin alloy of the tin alloy bump layer. Typically, the layer of Ni or Co can be formed by electrolytic plating.

According to an aspect of the present invention, the step of forming the tin alloy bump layer by plating includes a step of forming the tin alloy bump layer with a plating solution at a third temperature that is equal to or higher than the second temperature.

According to this aspect, the tin alloy bump layer is formed by plating at the third temperature that is equal to or higher than the second temperature. Therefore, the width of the resist opening at the time when the tin alloy bump layer is formed by plating is equal to or smaller than the width of the resist opening at the time when the enhanced barrier layer is formed by plating. Therefore, the width of the tin alloy bump layer is equal to or smaller than the width of the enhanced barrier layer, and when the tin alloy bump layer is reflowed, the tin alloy can be prevented from flowing beyond the enhanced barrier layer and from flowing down to and coming into contact with the copper wiring layer.

According to an aspect of the present invention, a substrate having a bump at a resist opening is provided. The substrate includes a copper wiring layer provided on the substrate, an enhanced barrier layer provided on the copper wiring layer, and a tin alloy bump layer on the enhanced barrier layer. The width of the enhanced barrier layer is greater than the width of the copper wiring layer.

According to this aspect, since the width of the enhanced barrier layer is greater than the width of the copper wiring layer, when the tin alloy bump layer is reflowed, the tin alloy can be prevented from flowing down to and coming into contact with the copper wiring layer.

According to an aspect of the present invention, the enhanced barrier layer covers at least a part of a side surface of the copper wiring layer.

According to this aspect, since the enhanced barrier layer covers at least a part of a side surface of the copper wiring layer, when the tin alloy bump layer is reflowed, the tin alloy can be prevented with higher reliability from flowing down to and coming into contact with the copper wiring layer.

According to an aspect of the present invention, the enhanced barrier layer contains one or more metals selected from a group consisting of Ni and Co.

According to this aspect, since the enhanced barrier layer is made of a material into which copper of the copper wiring layer is hard to diffuse, the copper of the copper wiring layer can be prevented from diffusing into the tin alloy of the tin alloy bump layer. Typically, the layer of Ni or Co can be formed by electrolytic plating.

### BRIEF DESCRIPTION OF DRAWINGS

FIG. 1 is a diagram showing a general arrangement of a plating apparatus that plates a substrate according to a first embodiment of the present invention.

FIG. 2 is a schematic side cross-sectional view of a plating bath shown in FIG. 1.

FIG. 3A is a partial cross-sectional view of a substrate for illustrating a method of manufacturing a substrate according to the first embodiment.

FIG. 3B is a partial cross-sectional view of the substrate for illustrating the method of manufacturing a substrate according to the first embodiment.

FIG. 3C is a partial cross-sectional view of the substrate for illustrating the method of manufacturing a substrate according to the first embodiment.

FIG. 3D is a partial cross-sectional view of the substrate for illustrating the method of manufacturing a substrate according to the first embodiment.

FIG. 3E is a partial cross-sectional view of the substrate for illustrating the method of manufacturing a substrate according to the first embodiment.

FIG. 3F is a partial cross-sectional view of the substrate for illustrating the method of manufacturing a substrate according to the first embodiment.

FIG. 3G is a partial cross-sectional view of the substrate for illustrating the method of manufacturing a substrate according to the first embodiment.

FIG. 4A is a partial cross-sectional view of a substrate for illustrating a method of manufacturing a substrate according to a second embodiment.

FIG. 4B is a partial cross-sectional view of the substrate for illustrating the method of manufacturing a substrate according to the second embodiment.

FIG. 4C is a partial cross-sectional view of the substrate for illustrating the method of manufacturing a substrate according to the second embodiment.

FIG. 4D is a partial cross-sectional view of the substrate for illustrating the method of manufacturing a substrate according to the second embodiment.

FIG. 4E is a partial cross-sectional view of the substrate for illustrating the method of manufacturing a substrate according to the second embodiment.

FIG. 4F is a partial cross-sectional view of the substrate for illustrating the method of manufacturing a substrate according to the second embodiment.

FIG. 5 is a diagram showing a general arrangement of a plating apparatus that plates a substrate according to a third embodiment.

FIG. 6A is a schematic diagram for illustrating a conventional process of manufacturing a substrate having a bump at a resist opening.

FIG. 6B is a schematic diagram for illustrating the conventional process of manufacturing a substrate having a bump at a resist opening.

FIG. 6C is a schematic diagram for illustrating the conventional process of manufacturing a substrate having a bump at a resist opening.

FIG. 6D is a schematic diagram for illustrating the conventional process of manufacturing a substrate having a bump at a resist opening.

FIG. 6E is a schematic diagram for illustrating the conventional process of manufacturing a substrate having a bump at a resist opening.

FIG. 6F is a schematic diagram for illustrating the conventional process of manufacturing a substrate having a bump at a resist opening.

### DESCRIPTION OF EMBODIMENTS

### First Embodiment

In the following, a first embodiment of the present invention will be described with reference to the drawings. In the drawings described below, the same or equivalent components are denoted by the same reference numerals, and redundant descriptions thereof will be omitted.

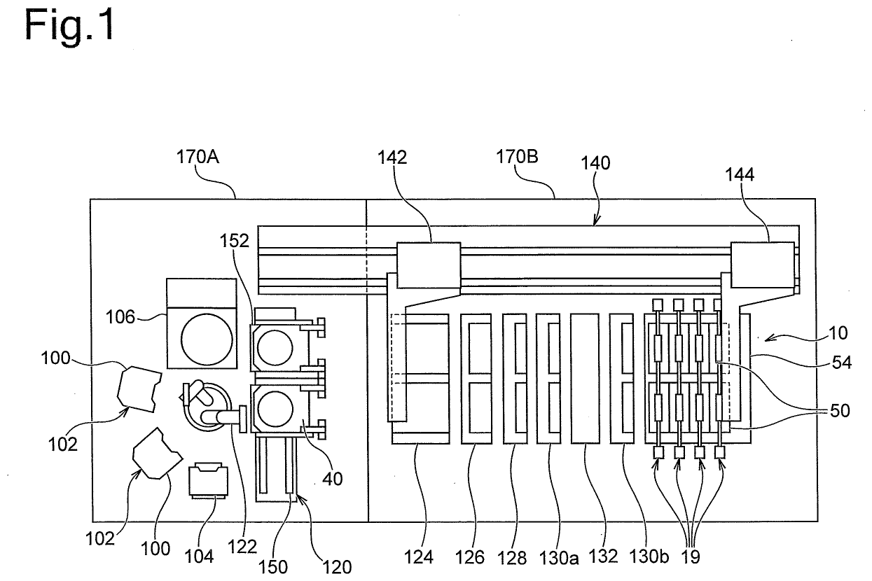

FIG. 1 is a diagram showing a general arrangement of a plating apparatus that plates a substrate according to the first embodiment of the present invention. As shown in FIG. 1, the plating apparatus is generally divided into a load/unload unit 170A that loads a substrate on a substrate holder 40 or unloads the substrate from the substrate holder 40 and a processing unit 170B that processes the substrate.

The load/unload unit 170A includes two cassette tables 102, an aligner 104 that orients an orientation flat or a notch of the substrate in a predetermined direction, and a spin rinse dryer 106 that dries the plated substrate by spinning the same at high rate. A cassette 100 that houses the substrate, such as a semiconductor wafer, is mounted on the cassette table 102. A substrate attaching/detaching unit 120 on which the substrate holder 40 is mounted for attaching or detaching of the substrate is provided near the spin rinse dryer 106. At the center of the units 100, 104, 106 and 120, a substrate transporting device 122, which is constituted by a transporting robot that transfers the substrate between the units, is arranged.

The substrate attaching/detaching unit 120 is provided with a flat mount plate 152 that is slidable in a horizontal direction on a rail 150. Two substrate holders 40 are mounted on the mount plate 152 in a horizontal position side by side. After a substrate is transferred between one of the substrate holders 40 and the substrate transporting device 122, the mount plate 152 is slid in the horizontal direction, and a substrate is transferred between the other substrate holder 40 and the substrate transporting device 122.

The processing unit 170B of the plating apparatus includes a stocker 124, a pre-wet bath 126, a pre-soak bath 128, a first cleaning bath 130a, a blow bath 132, a second cleaning bath 130b, and a plating bath 10. The stocker 124 keeps and temporarily stores the substrate holders 40. In the pre-wet bath 126, the substrate is immersed in pure water. In the pre-soak bath 128, an oxide film on a surface of a conductive layer, such as a seed layer, formed on a surface of the substrate is removed by etching. In the first cleaning bath 130a, the pre-soaked substrate and the substrate holder 40 are cleaned with a cleaning solution (such as pure water). In the blow bath 132, draining of the cleaned substrate is performed. In the second cleaning bath 130b, the substrate plated and the substrate holder 40 are cleaned with a cleaning solution. The stocker 124, the pre-wet bath 126, the pre-soak bath 128, the first cleaning bath 130a, the blow bath 132, the second cleaning bath 130b and the plating bath 10 are arranged in this order.

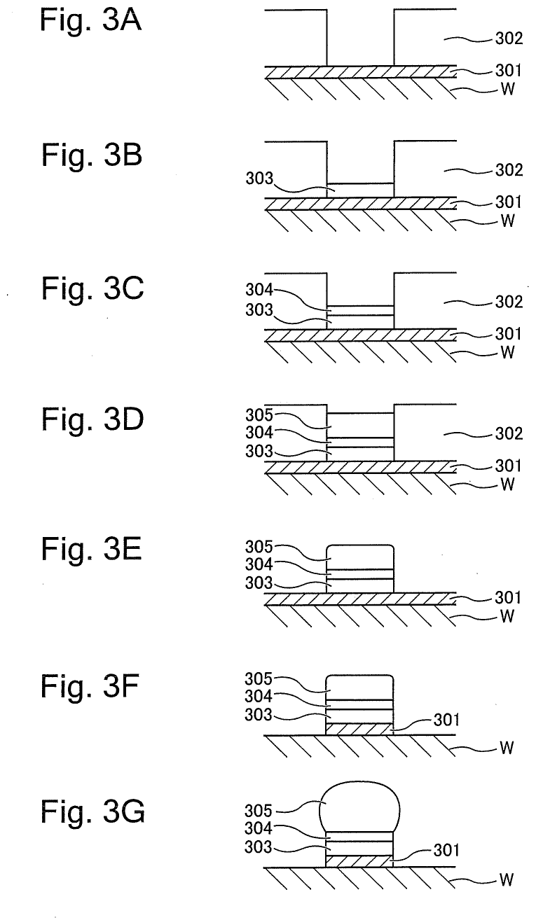

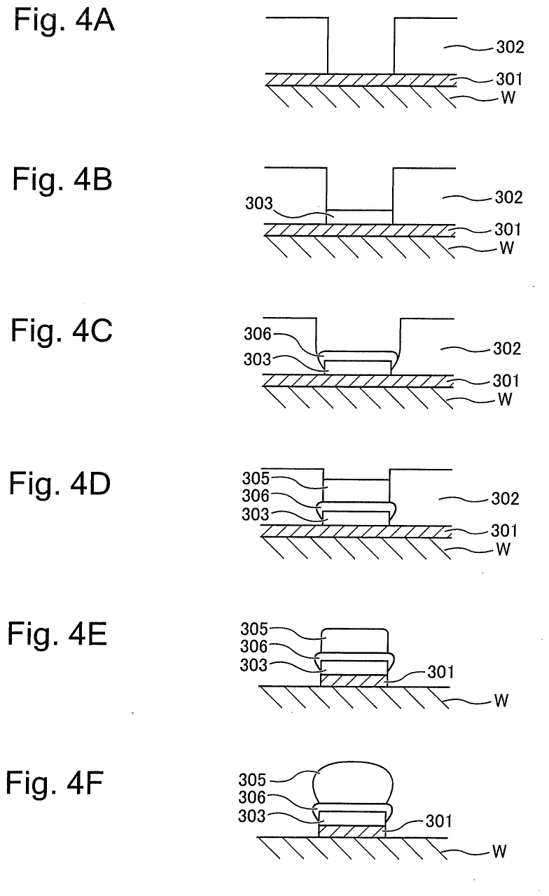

The plating bath 10 has a plurality of plating cells 50 provided with an overflow bath 54, for example. Each plating cell 50 is designed to house one substrate. The substrate is immersed in a plating solution held in the plating cell to plate the surface of the substrate. Specifically, the plurality of plating cells 50 include any one type selected from among a copper plating cell for forming the copper wiring layer described later, a nickel plating cell for forming the barrier layer described later, and a tin-silver plating cell for forming the tin alloy bump layer described later. As described later with reference to FIGS. 3A to 3G and 4A to 4F, if the metal layers are formed on the substrate in such a manner that the copper wiring layer is first formed, the barrier layer or enhanced barrier layer is then formed, and the tin alloy bump layer is finally formed, the substrate, which is an object to be plated, is sequentially plated by the plating apparatus that forms the copper wiring layer, then by the plating apparatus that forms the barrier layer or enhanced barrier layer, and finally by the plating apparatus that forms the tin alloy bump layer.

The plating apparatus has a substrate holder transporting device 140 that adopts a linear motor system, for example. The substrate holder transporting device 140 is arranged at the side of the components of the plating apparatus described above and transfers the substrate holder 40 with the substrate between the components. The substrate holder transporting device 140 has a first transporter 142 and a second transporter 144. The first transporter 142 is configured to transfer the substrate between the substrate attaching/detaching unit 120, the stocker 124, the pre-wet bath 126, the pre-soak bath 128, the first cleaning bath 130a and the blow bath 132. The second transporter 144 is configured to transfer the substrate between the first cleaning bath 130a, the second cleaning bath 130b, the blow bath 132 and the plating bath 10. In another embodiment, the plating apparatus may include only one of the first transporter 142 and the second transporter 144.

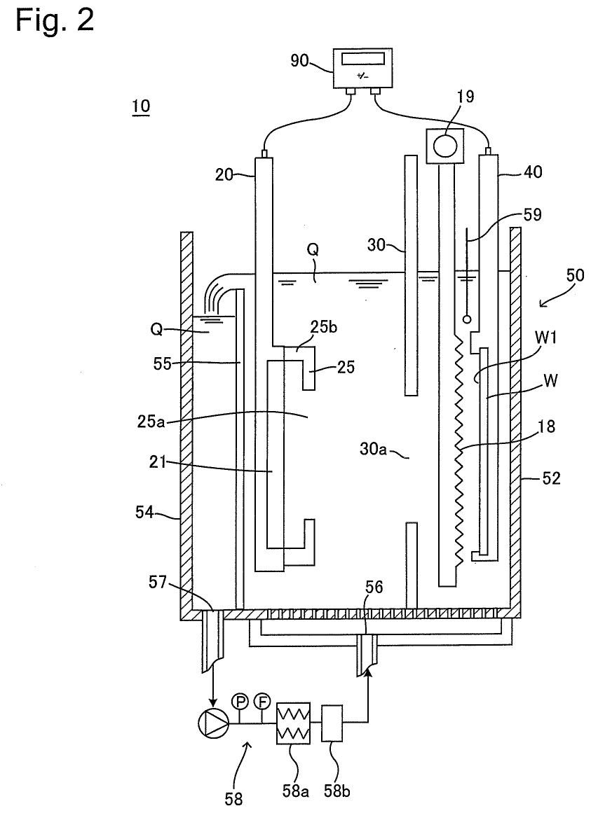

On the opposite sides of the overflow bath 54, paddle driving devices 19 are arranged that drive paddles 18 (see FIG. 2) that are arranged in the respective plating cells 50 and serve as stirring bars that agitate the plating solution in the plating cells 50.

FIG. 2 is a schematic side cross-sectional view of the plating bath 10 shown in FIG. 1. As shown in the drawing, the plating bath 10 has an anode holder 20 configured to hold an anode 21, the substrate holder 40 configured to hold the substrate W, and the plating cell 50 that houses the anode holder 20 and the substrate holder 40.

As shown in FIG. 2, the plating cell 50 has a plating processing bath 52 that holds a plating solution Q containing an additive, the overflow bath 54 that receives an overflow of the plating solution Q from the plating processing bath 52, and a partition wall 55 that separates the plating processing bath 52 and the overflow bath 54. The plating solution Q in the plating cell 50 can be any chemical solution, so that the copper wiring layer, the barrier layer and the tin alloy bump layer described later can be formed by plating.

The anode holder 20 holding the anode 21 and the substrate holder 40 holding the substrate W are immersed in the plating solution Q in the plating processing bath 52 and positioned with the anode 21 and a surface W1 to be plated of the substrate W being opposed to each other and substantially in parallel with each other. In the state where the anode 21 and the substrate W are immersed in the plating solution Q in the plating processing bath 52, a voltage is applied to the anode 21 and the substrate W by a plating power supply 90. Then, metal ions on the surface W1 to be plated of the substrate W are reduced, and a film is formed on the surface W1 to be plated. In the vicinity of the substrate W, a thermometer 59 that measures the temperature of the plating solution Q is arranged. The temperature measured by the thermometer 59 is transmitted to a controller (not shown) and fed back for controlling the plating cell 50.

The plating processing bath 52 has a plating solution supply port 56 for supplying the plating solution Q into the bath. The overflow bath 54 has a plating solution discharge port 57 for discharging an overflow of the plating solution Q from the plating processing bath 52. The plating solution supply port 56 is arranged in the bottom of the plating processing bath 52, and the plating solution discharge port 57 is arranged in the bottom of the overflow bath 54.

As the plating solution Q is supplied to the plating processing bath 52 through the plating solution supply port 56, the plating solution Q overflows from the plating processing bath 52 into the overflow bath 54 beyond the partition wall 55. The plating solution Q having flowed into the overflow bath 54 is discharged through the plating solution discharge port 57, and the temperature of the discharged plating solution Q is adjusted to a desired temperature by a temperature adjustment mechanism 58a, such as a heater or a chiller, of a plating solution circulation device 58. The controller (not shown) adjusts the temperature of the plating solution Q by adjusting the output of the temperature adjustment mechanism 58a with a PID control scheme or the like, based on the output of the thermometer 59. The thermometer 59 may be immersed in the plating solution Q as shown in the drawing or provided on the surface of the substrate holder 40 opposite to the substrate W. The plating solution Q adjusted to the desired temperature is passed through a filter 58b or the like of the plating solution circulation device 58 to remove impurities therefrom. The plating solution Q from which impurities have been removed is supplied to the plating processing bath 52 through the plating solution supply port 56 by the plating solution circulation device 58.

The anode holder 20 has an anode mask 25 that regulates an electric field between the anode 21 and the substrate W. The anode mask 25 is a member made of a dielectric material having a substantially planar shape, for example, and is arranged on a front surface of the anode holder 20. That is, the anode mask 25 is arranged between the anode 21 and the substrate holder 40. The anode mask 25 has a first opening 25a through which a current flowing between the anode 21 and the substrate W passes through in a substantially central part thereof The anode mask 25 has an anode mask attachment part 25b that integrally attaches the anode mask 25 to the anode holder 20 at an outer perimeter thereof.

The plating bath 10 further has a regulation plate 30 that regulates the electric field between the anode 21 and the substrate W. The regulation plate 30 is a member made of a dielectric material having a substantially planar shape, for example, and is arranged between the anode mask 25 and the substrate holder 40 (substrate W). The regulation plate 30 has a second opening 30a through which the current flowing between the anode 21 and the substrate W passes through.

Between the regulation plate 30 and the substrate holder 40, the paddle 18 that agitates the plating solution Q in the vicinity of the surface W1 to be plated of the substrate W. The paddle 18 is a member having a substantially rod-like shape and is arranged in the plating processing bath 52 to vertically extend. The paddle 18 is fixed to the paddle driving device 19 at one end thereof. The paddle 18 is horizontally moved along the surface W to be plated of the substrate W by the paddle driving device 19 to agitate the plating solution Q.

According to a method of manufacturing a substrate according to the first embodiment, in the plating cell 50 shown in FIG. 2, the temperature of the plating solution Q is adjusted to a desired temperature by the temperature adjustment mechanism 58a so that the resist layer formed on the substrate W is at a desired temperature. The resist layer formed on the substrate comes into contact with the plating solution Q during plating, the temperature of the plating solution Q and the temperature of the resist layer can be regarded as being substantially equal to each other. Therefore, in this specification, the temperature at the time when the substrate W is plated refers to the temperature of the plating solution Q or the temperature of the resist layer. In the following, the method of manufacturing a substrate according to the first embodiment will be described in detail.

FIGS. 3A to 3G are partial cross-sectional views of a substrate W for illustrating the method of manufacturing a substrate according to the first embodiment. As shown in FIG. 3A, according to the method of manufacturing a substrate according to the first embodiment, a substrate W on which a seed layer 301 made of copper or the like and a resist layer 302 on the seed layer 301 are formed is prepared. The substrate W is a substrate made of SiO₂ or Si, for example. The resist layer 302 has an opening, and the three-layered plating film described later is formed on the seed layer 301 exposed through the opening.

As shown in FIG. 3B, a copper wiring layer 303 is then formed in the opening of the resist layer 302. The copper wiring layer 303 is formed by electrolytic plating in the plating cell 50 shown in FIG. 2. The copper wiring layer 303 has a thickness of approximately 5 to 15 μm, for example. The temperature of the plating solution Q used when the copper wiring layer 303 is formed is set at approximately 25° C. (referred to as a first temperature hereinafter), from the viewpoints of the plating rate and the efficacy of the additive contained in the plating solution, for example. Therefore, the temperature of the resist layer 302 is also approximately 25° C. as with the plating solution Q.

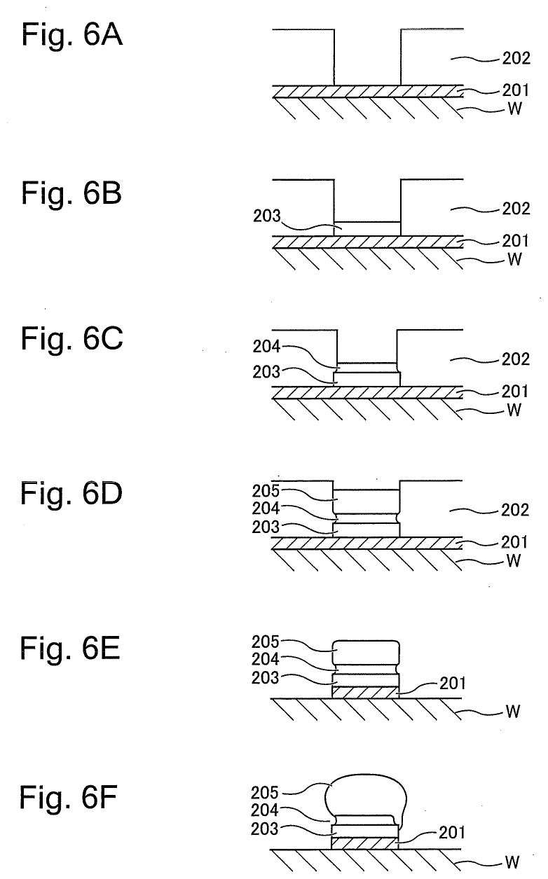

As shown in FIG. 3C, a barrier layer 304 containing Ni (which is an example of the barrier layer) is formed on the copper wiring layer 303. The barrier layer 304 has a thickness of approximately 1 to 10 μm, for example. The barrier layer 304 is formed by electrolytic plating in a different plating cell 50 than the plating cell 50 in which the copper wiring layer 303 is formed by plating. In the first embodiment, the temperature of the plating solution used when the barrier layer 304 is formed (referred to as a second temperature hereinafter) is set to be approximately equal to the first temperature. In other words, according to the method of manufacturing a substrate according to the first embodiment, the barrier layer 304 is formed by plating at a lower temperature than in the conventional substrate manufacturing process shown in FIGS. 6A to 6F. According to one embodiment, the second temperature is approximately 25° C., which is equal to the first temperature. Therefore, the temperature of the resist layer 302 at the time when the barrier layer 304 is formed is approximately equal to the temperature of the resist layer 302 at the time when the copper wiring layer 303 is formed, so that the width of the opening in the resist layer 302 at the time when the barrier layer 304 is formed by plating is close to the width of the opening in the resist layer 302 at the time when the copper wiring layer 303 is formed by plating. As a result, the width of the barrier layer 304 is close to the width of the copper wiring layer 303. In this specification, the “width” means the outer diameter of each layer when the opening in the resist layer 302 has a substantially circular shape and means the distance between apexes of each polygonal layer when the opening in the resist layer 302 has a polygonal shape.

As shown in FIG. 3D, a tin alloy bump layer 305 containing tin and silver is then formed on the barrier layer 304. The tin alloy bump layer 305 has a thickness of approximately 10 to 50 μm, for example. The tin alloy bump layer 305 is formed by electrolytic plating in a different plating cell 50 than the plating cell 50 in which the copper wiring layer 303 is formed by plating and the plating cell 50 in which the barrier layer 304 is formed by plating. The temperature of the plating solution used when tin alloy bump layer 305 is formed (referred to as a third temperature hereinafter) is preferably set at a temperature equal to or higher than the second temperature. According to one embodiment, the third temperature is approximately 25° C., which is equal to the second temperature. Therefore, the temperature of the resist layer 302 at the time when the tin alloy bump layer 305 is formed is equal to or higher than the temperature of the resist layer 302 at the time when the barrier layer 304 is formed, so that the width of the opening in the resist layer 302 at the time when the tin alloy bump layer 305 is formed by plating is equal to or smaller than the width of the opening in the resist layer 302 at the time when the barrier layer 304 is formed by plating. As a result, the width of the tin alloy bump layer 305 is equal to or smaller than the width of the barrier layer 304.

After that, the resist layer 302 is removed by a resist stripping device (see FIG. 3E), and the seed layer 301 is etched into a more appropriate shape by an etching device (see FIG. 3F). According to the method of manufacturing a substrate according to the first embodiment described above, as shown in FIG. 3F, the width of the barrier layer 304 is close to the width of the copper wiring layer 303. The width of the tin alloy bump layer 305 is preferably equal to or smaller than the width of the barrier layer 304.

Since the width of the barrier layer 304 is close to the width of the copper wiring layer 303 as described above, when the tin alloy bump layer 305 is reflowed, the reflowed tin alloy bump layer 305 is less likely to flow down along the side surface of the barrier layer 304, compared with the case shown in FIG. 6E where the barrier layer 204 has a substantially smaller width than the copper wiring layer 203. Therefore, as shown in FIG. 3G, the reflowed tin alloy bump layer 305 can maintain a desired spherical shape, and the tin alloy bump layer 305 can be prevented from coming into contact with the copper wiring layer 303.

As described above, according to the first embodiment, the barrier layer 304 on the copper wiring layer 303 is formed by plating at a temperature approximately equal to the temperature at the time when the copper wiring layer 303 is formed by plating. Therefore, the width of the opening in the resist layer 302 at the time when the barrier layer 304 is formed by plating is close to the width of the opening in the resist layer 302 at the time when the copper wiring layer 303 is formed by plating. As a result, the width of the barrier layer 304 is close to the width of the copper wiring layer 303, and when the tin alloy bump layer 305 is reflowed, the tin alloy can be prevented from flowing to and coming into contact with the copper wiring layer 303. In the conventional process shown in FIGS. 6A to 6F, the temperature of the plating solution used when the barrier layer 204 is formed is set at approximately 40° C., from the viewpoints of the plating rate and the efficacy of the additive contained in the plating solution. To maintain high plating rate is an important factor of the plating process, and the temperature of the plating solution is generally set so as to provide an optimal plating rate. However, according to the first embodiment, by setting the temperature of the plating solution used when the barrier layer 304 is formed by plating to be substantially lower than the temperature used for the conventional process, the width of the barrier layer 304 can be brought closer to the width of the copper wiring layer 303, although the plating rate and the efficacy of the additive degrade.

Although the barrier layer 304 has been described as containing Ni as an example in the first embodiment, the present invention is not limited thereto, and the barrier layer 304 may contain one or more metals selected from a group consisting of Ni and Co. These metals are materials into which copper of the copper wiring layer 303 is hard to diffuse, so that the copper can be prevented from diffusing into the tin alloy bump layer 305. In addition, although the tin alloy bump layer 305 has been described as containing tin and silver as an example in the first embodiment, the present invention is not limited to this, and the tin alloy bump layer 305 may contain tin and silver or tin and copper.

The “temperature approximately equal to a different temperature” in this specification means that the difference between the two temperatures is smaller than 5° C., or preferably equal to or smaller than 2.5° C., or more preferably equal to or smaller than 1° C. If the difference between the first temperature and the second temperature is smaller than 5° C., the width of the barrier layer 304 and the width of the copper wiring layer 303 are sufficiently close to each other, and when the tin alloy bump layer 305 is reflowed, the tin alloy can be prevented from flowing down to and coming into contact with the copper wiring layer 303. If the difference between the first temperature and the second temperature is equal to or smaller than 2.5° C., the width of the barrier layer 304 and the width of the copper wiring layer 303 are even closer to each other, and when the tin alloy bump layer 305 is reflowed, the tin alloy can be prevented with higher reliability from flowing down to and coming into contact with the copper wiring layer 303. Furthermore, if the difference between the first temperature and the second temperature is equal to or smaller than 1° C., the width of the barrier layer 304 and the width of the copper wiring layer 303 are substantially equal to each other, and when the tin alloy bump layer 305 is reflowed, the tin alloy can be prevented with even higher reliability from flowing down to and coming into contact with the copper wiring layer 303.

### Second Embodiment

Next, a method of manufacturing a substrate according to a second embodiment will be described. The method of manufacturing a substrate according to the second embodiment can be performed with the plating apparatus shown in FIGS. 1 and 2. According to the method of manufacturing a substrate according to the second embodiment, as with the method according to the first embodiment, in the plating cell 50 shown in FIG. 2, the temperature of the plating solution Q is adjusted to a desired temperature by the temperature adjustment mechanism 58a so that the resist layer formed on the substrate W is at a desired temperature. In the following, the method of manufacturing a substrate according to the second embodiment will be described in detail.

FIGS. 4A to 4F are partial cross-sectional views of a substrate W for illustrating the method of manufacturing a substrate according to the second embodiment. As shown in FIG. 4A, according to the method of manufacturing a substrate according to the second embodiment, a substrate W on which a seed layer 301 made of copper or the like and a resist layer 302 on the seed layer 301 are formed is prepared.

As shown in FIG. 4B, a copper wiring layer 303 is then formed in an opening of the resist layer 302. The copper wiring layer 303 is formed by electrolytic plating in the plating cell 50 shown in FIG. 2. The copper wiring layer 303 has a thickness of approximately 5 to 15 μm, for example. The temperature of the plating solution Q used when the copper wiring layer 303 is formed is set at approximately 25° C. (referred to as a first temperature hereinafter), from the viewpoints of the plating rate and the efficacy of the additive contained in the plating solution, for example. Therefore, the temperature of the resist layer 302 is also approximately 25° C. as with the plating solution Q.

As shown in FIG. 4C, an enhanced barrier layer 306 containing Ni is formed on the copper wiring layer 303. The enhanced barrier layer 306 has a thickness of approximately 1 to 10 μm, for example. The enhanced barrier layer 306 is formed by electrolytic plating in a different plating cell 50 than the plating cell 50 in which the copper wiring layer 303 is formed by plating.

In the second embodiment, the temperature of the plating solution used when the enhanced barrier layer 306 is formed (referred to as a second temperature hereinafter) is set to be lower than the first temperature. In other words, according to the method of manufacturing a substrate according to the second embodiment, the enhanced barrier layer 306 is formed by plating at a lower temperature than in the conventional substrate manufacturing process shown in FIGS. 6A to 6F. According to one embodiment, the second temperature is approximately 20° C. Therefore, the temperature of the resist layer 302 at the time when the enhanced barrier layer 306 is formed is lower than the temperature of the resist layer 302 at the time when the copper wiring layer 303 is formed, so that the width of the opening in the resist layer 302 at the time when the enhanced barrier layer 306 is formed by plating is greater than the width of the opening in the resist layer 302 at the time when the copper wiring layer 303 is formed by plating. As a result, the width of the enhanced barrier layer 306 is greater than the width of the copper wiring layer 303.

In addition, since the width of the opening in the resist layer 302 at the time when the enhanced barrier layer 306 is formed by plating is greater than the width of the opening in the resist layer 302 at the time when the copper wiring layer 303 is formed by plating, a fine gap occurs between the side surface of the copper wiring layer 303 and the resist layer 302. As a result, when the enhanced barrier layer 306 is formed by plating, the plating solution Q enters the gap between at least a part of the side surface of the copper wiring layer 303 and the resist layer 302, so that the enhanced barrier layer 306 is also formed by plating on that part of the side surface of the copper wiring layer 303. That is, as shown in FIG. 4C, the enhanced barrier layer 306 covers at least a part of the side surface of the copper wiring layer 303.

The second temperature is preferably lower than the first temperature by 5° C. or more. If this condition is satisfied, the width of the enhanced barrier layer 306 can be sufficiently greater than the width of the copper wiring layer, and the area of the side surface of the copper wiring layer 303 covered by the enhanced barrier layer 306 can be increased. In addition, the second temperature is preferably equal to or higher than 15° C. Some kinds of plating solution Q used for forming the enhanced barrier layer 306 by plating contain boric acid. Boric acid can be deposited if the temperature of the plating solution Q is lower than 15° C. According to the second embodiment, since the second temperature is equal to or higher than 15° C., boric acid can be prevented from being deposited from the plating solution Q used for forming the enhanced barrier layer 306 by plating.

As shown in FIG. 4D, a tin alloy bump layer 305 containing tin and silver is then formed on the enhanced barrier layer 306. The tin alloy bump layer 305 has a thickness of approximately 10 to 50 μm, for example. The tin alloy bump layer 305 is formed by electrolytic plating in a different plating cell 50 than the plating cell 50 in which the copper wiring layer 303 is formed by plating and the plating cell 50 in which the enhanced barrier layer 306 is formed by plating. The temperature of the plating solution used when tin alloy bump layer 305 is formed (referred to as a third temperature hereinafter) is preferably set at a temperature equal to or higher than the second temperature. According to one embodiment, the third temperature is approximately 25° C. Therefore, the temperature of the resist layer 302 at the time when the tin alloy bump layer 305 is formed is equal to or higher than the temperature of the resist layer 302 at the time when the enhanced barrier layer 306 is formed, so that the width of the opening in the resist layer 302 at the time when the tin alloy bump layer 305 is formed by plating is equal to or smaller than the width of the opening in the resist layer 302 at the time when the enhanced barrier layer 306 is formed by plating. As a result, the width of the tin alloy bump layer 305 is equal to or smaller than the width of the enhanced barrier layer 306.

After that, the resist layer 302 is removed by a resist stripping device, and the seed layer 301 is etched into a more appropriate shape by an etching device (see FIG. 4E). According to the method of manufacturing a substrate according to the second embodiment described above, as shown in FIG. 4E, the width of the enhanced barrier layer 306 is greater than the width of the copper wiring layer 303. In addition, the enhanced barrier layer 306 preferably covers at least a part of the side surface of the copper wiring layer 303. In addition, the width of the tin alloy bump layer 305 is preferably equal to or smaller than the width of the enhanced barrier layer 306.

Since the width of the barrier layer 304 is greater than the width of the copper wiring layer 303 as described above, when the tin alloy bump layer 305 is reflowed, the reflowed tin alloy bump layer 305 is less likely to flow down along the side surface of the barrier layer 304, compared with the case shown in FIG. 6E where the barrier layer 204 has a substantially smaller width than the copper wiring layer 203. Therefore, as shown in FIG. 4F, the reflowed tin alloy bump layer 305 can maintain a desired spherical shape, and the tin alloy bump layer 305 can be prevented from coming into contact with the copper wiring layer 303.

As described above, according to the second embodiment, the enhanced barrier layer 306 on the copper wiring layer 303 is formed by plating at a temperature lower than the temperature at the time when the copper wiring layer 303 is formed by plating. Therefore, the width of the opening in the resist layer 302 at the time when the enhanced barrier layer 306 is formed by plating is greater than the width of the opening in the resist layer 302 at the time when the copper wiring layer 303 is formed by plating. As a result, the width of the enhanced barrier layer 306 is greater than the width of the copper wiring layer 303, and when the tin alloy bump layer 305 is reflowed, the tin alloy can be prevented with higher reliability from flowing to and coming into contact with the copper wiring layer 303. In addition, in the second embodiment, since the enhanced barrier layer 306 covers at least a part of the side surface of the copper wiring layer 303, when the tin alloy bump layer 305 is reflowed, the tin alloy can be prevented with even higher reliability from coming into contact with the copper wiring layer 303. In the conventional process shown in FIGS. 6A to 6F, the temperature of the plating solution used when the barrier layer 204 is formed is set at approximately 40° C., from the viewpoints of the plating rate and the efficacy of the additive contained in the plating solution. To maintain high plating rate is an important factor of the plating process, and the temperature of the plating solution is generally set so as to provide an optimal plating rate. However, according to the second embodiment, by setting the temperature of the plating solution used when the enhanced barrier layer 306 is formed by plating to be substantially lower than the temperature used for the conventional process, the width of the enhanced barrier layer 306 can be greater than the width of the copper wiring layer 303, although the plating rate and the efficacy of the additive degrade.

Although the enhanced barrier layer 306 has been described as containing Ni as an example in the second embodiment, the present invention is not limited thereto, and the enhanced barrier layer 306 may contain one or more metals selected from a group consisting of Ni and Co. These metals are materials into which copper of the copper wiring layer 303 is hard to diffuse, so that the copper can be prevented from diffusing into the tin alloy bump layer 305. In addition, although the tin alloy bump layer 305 has been described as containing tin and silver as an example in the second embodiment, the present invention is not limited to this, and the tin alloy bump layer 305 may contain tin and silver or tin and copper.

### Third Embodiment

Next, a third embodiment of the present invention will be described. According to the third embodiment, the configuration of the plating apparatus differs from the plating apparatus shown in FIG. 1. The methods of manufacturing a substrate according to the first and second embodiments described above can be performed with the plating apparatus according to the third embodiment described below.

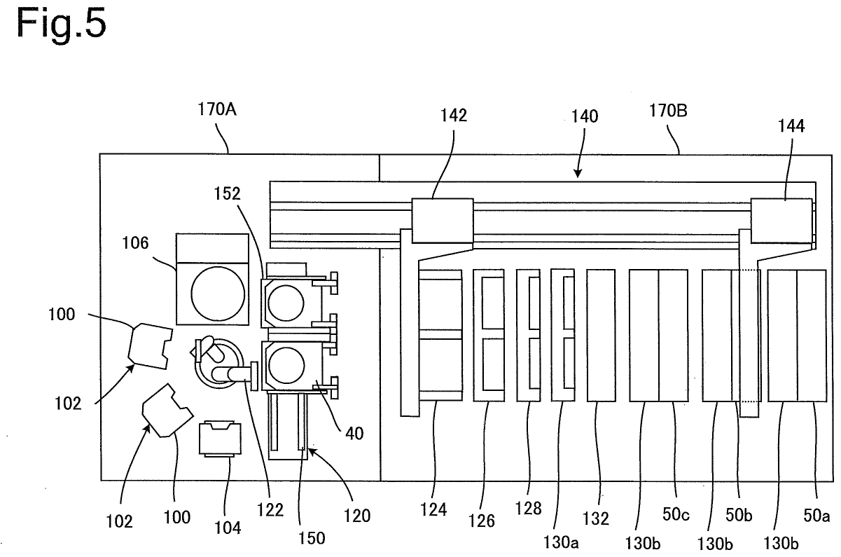

FIG. 5 is a diagram showing a general arrangement of a plating apparatus that plates a substrate according to the third embodiment. As shown in FIG. 5, the plating apparatus according to the third embodiment differs from the plating apparatus shown in FIG. 1 in that the plating apparatus has three plating cells 50a, 50b and 50c and each of the plating cells 50a, 50b and 50c is provided with a second cleaning bath 130b. The other components are the same as those of the plating apparatus shown in FIG. 1, so that descriptions thereof will be omitted.

As shown in the drawing, in the plating apparatus, in a subsequent stage to the blow bath 132, the plating cell 50c provided with the second cleaning bath 130b, the plating cell 50b provided with the second cleaning bath 130b, and the plating cell 50a provided with the second cleaning bath 130b are arranged in this order. The plating cells 50a, 50b and 50c have the same configuration as the plating cell 50 shown in FIG. 2 (although not shown, each of the plating cells 50a, 50b and 50c is provided with a paddle). The plating cell 50a is a plating cell in which the copper wiring layer 303 shown in FIGS. 3A to 3F and FIGS. 4A to 4F is formed. The plating cell 50b is a plating cell in which the barrier layer 304 shown in FIGS. 3A to 3F or the enhanced barrier layer 306 shown in FIGS. 4A to 4F is formed. The plating cell 50c is a plating cell in which the tin alloy bump layer 305 shown in FIGS. 3A to 3F and FIGS. 4A to 4F is formed.

When the plating apparatus shown in FIG. 5 forms the copper wiring layer 303, the barrier layer 304 or the enhanced barrier layer 306 and the tin alloy bump layer 305, the substrate is transferred to the plating cell 50a after being processed in the pre-wet bath 126, the pre-soak bath 128 and the first cleaning bath 130a. The temperature of the cleaning solution in the first cleaning bath 130a is preferably equal to the temperature of the plating solution in the subsequent plating cell 50a. If this condition is satisfied, when the substrate is immersed in the plating solution in the plating cell 50a, the temperature of the plating solution can be prevented from decreasing or increasing.

After the copper wiring layer 303 is formed on the substrate in the plating cell 50a, the substrate is transferred to the second cleaning bath 130b provided for the plating cell 50a and cleaned therein. The temperature of the cleaning solution in the second cleaning bath 130b is preferably equal to the temperature of the plating solution in the subsequent plating cell 50b. If this condition is satisfied, when the substrate is immersed in the plating solution in the plating cell 50b, the temperature of the plating solution can be prevented from decreasing or increasing.

The substrate with the copper wiring layer 303 formed thereon is then transferred to the plating cell 50b. After the barrier layer 304 or the enhanced barrier layer 306 is formed in the plating cell 50b, the substrate is transferred to the second cleaning bath 130b provided for the plating cell 50b and cleaned therein. The temperature of the cleaning solution in the second cleaning bath 130b is preferably equal to the temperature of the plating solution in the subsequent plating cell 50c. If this condition is satisfied, when the substrate is immersed in the plating solution in the plating cell 50c, the temperature of the plating solution can be prevented from decreasing or increasing.

The substrate with the barrier layer 304 or the enhanced barrier layer 306 formed thereon is then transferred to the plating cell 50c. After the tin alloy bump layer 305 is formed in the plating cell 50c, the substrate is transferred to the second cleaning bath 130b provided for the plating cell 50c and cleaned therein. The cleaned substrate is transferred to the blow bath 132, and draining of the substrate is performed. The substrate is then detached from the substrate holder 40 in the substrate attaching/detaching unit 120, dried by the spin rinse dryer 106, and then housed in the cassette 100.

As described above, since the plating apparatus shown in FIG. 5 has three plating cells 50a, 50b and 50c, the plating apparatus can form all of the copper wiring layer 303, the barrier layer 304 or the enhanced barrier layer 306, and the tin alloy bump layer 305.

Although embodiments of the present invention have been described above, the embodiments of the present invention described above are given to facilitate understanding of the present invention but are not intended to limit the present invention. Of course, many modifications or alterations can be made without departing from the spirit of the present invention, and the present invention includes equivalents thereof. In addition, as far as at least some of the problems described above can be solved, or at least some of the effects described above can be achieved, any combination of components described in the claims and the specification is possible, and any of the components can be omitted.

### REFERENCE SIGNS LIST

201 seed layer

202 resist layer

203 copper wiring layer

204 barrier layer

205 tin alloy bump layer

301 seed layer

302 resist layer

303 copper wiring layer

304 barrier layer

305 tin alloy bump layer

306 enhanced barrier layer

W substrate

1. A method of manufacturing a substrate having a bump at a resist opening, comprising:
a step of forming a copper wiring layer on the substrate by plating with a plating solution at a first temperature;
a step of forming a barrier layer on the copper wiring layer by plating with a plating solution at a second temperature that is approximately equal to the first temperature; and
a step of forming a tin alloy bump layer on the barrier layer by plating.

2. The method of manufacturing a substrate according to claim 1, wherein the difference between the first temperature and the second temperature is less than 5° C.

3. The method of manufacturing a substrate according to claim 2, wherein the difference between the first temperature and the second temperature is 2.5° C. or less.

4. The method of manufacturing a substrate according to claim 3, wherein the difference between the first temperature and the second temperature is 1° C. or less.

5. The method of manufacturing a substrate according to any one of claim 1, wherein the barrier layer contains one or more metals selected from a group consisting of Ni and Co.

6. A method of manufacturing a substrate having a bump at a resist opening, comprising:
a step of forming a copper wiring layer on the substrate by plating with a plating solution at a first temperature;
a step of forming an enhanced barrier layer on the copper wiring layer by plating with a plating solution at a second temperature that is lower than the first temperature; and
a step of forming a tin alloy layer on the enhanced barrier layer by plating.

7. The method of manufacturing a substrate according to claim 6, wherein a width of the enhanced barrier layer is greater than a width of the copper wiring layer.

8. The method of manufacturing a substrate according to claim 7, wherein the enhanced barrier layer covers at least a part of a side surface of the copper wiring layer.

9. The method of manufacturing a substrate according to any one of claim 6, wherein the second temperature is lower than the first temperature by 5° C. or more and is equal to or higher than 15° C.

10. The method of manufacturing a substrate according to any one of claim 6, wherein the enhanced barrier layer contains one or more metals selected from a group consisting of Ni and Co.

11. The method of manufacturing a substrate according to any one of claim 1, wherein the step of forming the tin alloy bump layer by plating includes a step of forming the tin alloy bump layer with a plating solution at a third temperature that is equal to or higher than the second temperature.

12. A substrate having a bump at a resist opening, comprising:
a copper wiring layer provided on the substrate;
an enhanced barrier layer provided on the copper wiring layer; and
a tin alloy bump layer on the enhanced barrier layer,
wherein a width of the enhanced barrier layer is greater than a width of the copper wiring layer.

13. The substrate according to claim 12, wherein the enhanced barrier layer covers at least a part of a side surface of the copper wiring layer.

14. The substrate according to claim 12, wherein the enhanced barrier layer contains one or more metals selected from a group consisting of Ni and Co.
